(19) United States
(12) Patent Application Publication
(10) Pub. No.: US 2026/0047024 A1
(43) Pub. Date: Feb. 12, 2026

(54) HOUSING FOR AN ELECTRICAL COMPONENT

(71) Applicant: MAHLE International GmbH, Stuttgart (DE)

(72) Inventors: Achim Gommel, Weil der Stadt (DE); Hans Christian Uibeleisen, Backnang (DE); Volker Kirschner, Muehlacker (DE); Oliver Fritz, Aichtal (DE); Tihomir Angelov, Ludwigsburg (DE)

(21) Appl. No.: 19/296,910

(22) Filed: Aug. 11, 2025

(30) Foreign Application Priority Data
Aug. 12, 2024 (DE) 102024122938.1

(51) Int. Cl. H05K 5/03

(52) U.S. Cl. CPC H05K 5/03

(57) ABSTRACT

A housing for an electrical component may include a service cover and a touch protection cover. The service cover may close a service opening. The touch protection cover may be arranged under the service cover and may also close the service opening. The touch protection cover may need to be removed to access the service opening and/or an interior space of the housing.

### CROSS-REFERENCE TO RELATED APPLICATION

This application claims priority to German Patent Application No. DE 102024122938.1, filed on Aug. 12, 2024, the contents of which is hereby incorporated by reference in its entirety.

### TECHNICAL FIELD

The present invention relates to a housing for an electrical component.

### BACKGROUND

Housings for electrical components, such as converter housings, are well known and already in widespread use. In order to be able to carry out service work on an electrical component arranged in the housing, for example a converter, such as replacing fuses, many housings of this type are provided with a service cover which, when removed, provides access to an interior space of the housing in which the electrical component is arranged.

However, a disadvantage of housings known from the prior art is that, if the electrical component is still live, removal of the service cover provides unprotected and direct access to the electrical component, which may pose a risk to the life and limb of a service technician.

### SUMMARY

The present invention therefore addresses the problem of providing a housing for an electrical component that both simplifies maintenance and makes it safer.

According to the invention, this problem is solved by the subject matter of the independent claim(s). Advantageous embodiments are the subject of the dependent claim(s).

The present invention is based on the general idea of providing, in a housing for an electrical component with a service opening, in addition to a removable service cover, a touch protection cover arranged below the service cover, which, after removal of the service cover, prevents direct access to parts of the electrical component that may be live. The housing for an electrical component according to the invention has the aforementioned service cover, which closes a service opening in the housing. A touch protection cover is arranged under the service cover, which also closes this service opening and must be removed to access the interior space of the housing. If, for example, a service technician removes the service cover from the housing to perform maintenance work, he will immediately encounter the touch protection cover that still closes the service opening. Warning notices regarding potentially live electrical voltage may be printed on this touch protection cover, for example, so that the service technician must first remove the touch protection cover closing the service opening in order to access the electrical component. This provides additional safety for the service technician, for example, to protect them from accidental electric shock.

In an advantageous further development of the housing according to the invention, the touch protection cover is connected to the housing by means of a loss prevention device, wherein the service cover cannot be fixed to the housing in such a way as to close the service opening, provided that the touch protection cover does not close the service opening and, in particular, the loss prevention device is not stowed away accordingly. The loss prevention device can, for example, be designed as a safety cable connected to the housing on one side and to the touch protection cover on the other. If an attempt is made to fix the service cover to the housing in such a way that it closes the service opening without first positioning the touch protection cover on the service opening and stowing the loss prevention device, the touch protection cover will continue to hang out of the service opening over the loss prevention device, which will prevent the service cover from fitting tightly onto one edge of the service opening, as the loss prevention device extends beyond the edge. This ensures that the service technician reliably closes the service opening with the touch protection cover in place, so that even a subsequent service technician cannot gain direct access to the electrical component after removing the service cover and thus risk electric shock from an electrical component that is still live.

In an advantageous further development of the housing according to the invention, the loss prevention device is designed as a safety cable, in particular as a wire or plastic rope. Such a safety cable, especially one made of wire, is not only inexpensive to manufacture, but also reliably fulfills the purpose of the loss prevention device. Two tabs arranged at both ends of the safety cable can be used to connect it to the housing on one side and to the touch protection cover on the other side, in particular by means of screws. A wire safety cable offers the major advantage of providing extremely wear-resistant loss prevention device that reliably fulfills its function throughout the entire service life of the housing. A loss prevention device designed as a plastic cord offers the advantage that it does not conduct electricity.

In another advantageous embodiment of the housing according to the invention, two measuring openings for a voltage tester are arranged in the touch protection cover. In addition to a warning notice arranged on the touch protection cover, the touch protection cover can thus also have two measuring openings for a voltage tester, through which the measuring tips of the voltage tester can be guided through the touch protection cover to live parts of the electrical component arranged in the housing. This allows a service technician to quickly and reliably determine whether the electrical component arranged in the housing is live or not, and thus whether there is a danger to life and limb or whether the electrical component must first be disconnected from the power supply.

In a preferred further development of the housing according to the invention, in particular for a high-voltage electrical component, the electrical component is designed as a current transformer, in particular as a converter. A converter is located at connection points between different voltage levels in a direct current circuit.

The housing itself can be made of plastic, in particular as a plastic injection molded part, and can therefore be manufactured not only cost-effectively but also to a high standard of quality.

In another advantageous embodiment of the housing according to the invention, the service cover is screwed to the housing. Screwing the service cover to the housing allows the service cover to be securely fastened to the housing and also makes it easy to remove the service cover from the housing during installation by loosening the individual screws. If screws with special screw heads or screw openings are used, the screws can also form a kind of lock, so that a service technician needs a corresponding bit as a key to loosen the screws on the service cover. This makes it at least more difficult for unauthorized persons to gain access.

In addition or as an alternative, according to a particularly preferred embodiment, the touch protection cover can also be screwed to the housing. Once the service technician has removed the service cover, they will encounter the touch protection cover, which is marked with a warning notice, for example. To remove the touch protection cover, it may be necessary to remove another screw, for example, which at least makes direct and, in particular, improper access to the electrical component arranged in the housing more difficult. The screws connecting the touch protection cover to the housing can also have special screw heads so that the touch protection cover can only be removed with a matching and complementary bit, which reliably prevents unauthorized access.

In a particularly preferred embodiment of the housing according to the invention, a sealing gasket is arranged between the service cover and the housing. In order to reliably ensure the functionality of electrical components in the housing, water must be prevented from entering the housing. This can be achieved relatively easily by means of a sealing gasket arranged between the housing and the service cover, wherein such a sealing gasket can be designed, for example, as a sealing cord with a round cross-section.

Other important features and advantages of the invention can be seen from the dependent claims, from the drawings and from the associated description of the figure based on the drawings.

It is understood that the above-mentioned features and those yet to be explained below can be used not only in the combination indicated in each case, but also in other combinations or on their own, without deviating from the scope of the present invention. The above-mentioned components of a superordinate unit, such as a device, an apparatus, or an arrangement, which are designated separately, can form separate parts or components of this unit or be integral areas or sections of this unit, even if this is shown differently in the drawings.

Preferred exemplary embodiments of the invention are shown in the drawings by way of example and will be explained in more detail in the following description, wherein identical reference numbers refer to identical or similar or functionally identical elements.

### BRIEF DESCRIPTION OF THE DRAWINGS

They show, each schematically,

FIG. 1 shows a view of a housing according to the invention with a service cover closing a service opening.

FIG. 2 shows the same arrangement as in FIG. 1, but with the service cover removed and a touch protection cover arranged underneath to close the service opening. H

### DETAILED DESCRIPTION

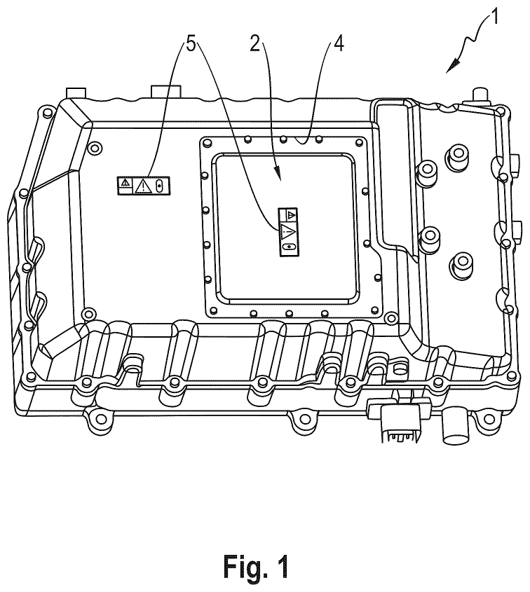

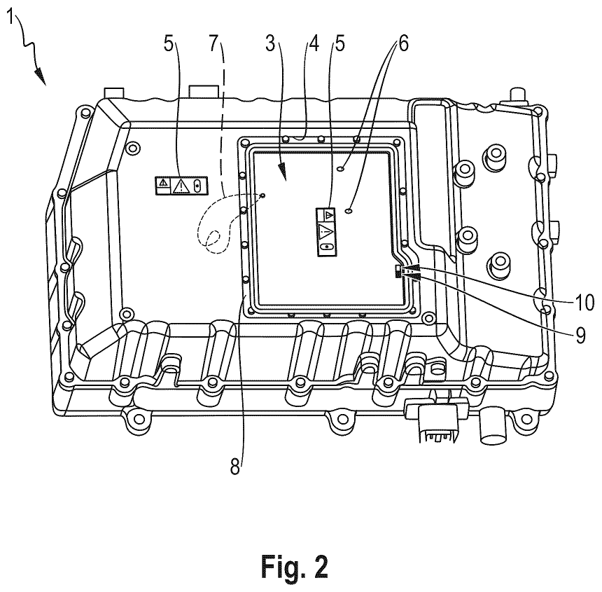

According to FIGS. 1 and 2, a housing 1 according to the invention for an electrical component, which is not shown in FIGS. 1 and 2 and which may be designed, for example, as a converter, has a service cover 2 which closes an underlying service opening 4 (see FIG. 1). A touch protection cover 3 (see FIG. 2), which also closes the service opening 4, and an additional interlock switch 9 are arranged under the service cover 2, wherein the touch protection cover 3 must also be removed to access the service opening 4 or an interior space in the housing 1. The service cover 2 activates the interlock switch 9 and interrupts the interlock circuit when the service cover 2 is removed, i.e., the high voltage is then switched off. For this purpose, a corresponding cutout or recess 10 is provided in the touch protection cover 3, through which the interlock switch 9 can interact with the service cover 2. Since the high voltage requires a certain amount of time to dissipate, the removal of the touch protection cover 3 is designed with various screws so that it takes a certain amount of time to remove the cover. During this time, the high voltage must be dissipated.

The touch protection cover 3 provided according to the invention offers the great advantage that direct and potentially dangerous access to the electrical component arranged in the housing 1 is not possible merely by removing the service cover 2. Since the electrical component arranged in housing 1 may be live, direct and immediate access by simply removing the service cover 2 could pose a high risk to a service technician who overlooks the warning notice 5 affixed to the service cover 2.

However, with the housing 1 according to the invention, the service technician does not have direct access to the electrical component arranged in the housing 1 after removing the service cover 2, as this direct access is prevented by the touch protection cover 3 after the service cover 2 has been removed.

Two measuring openings 6 for a voltage tester can be arranged in the touch protection cover 3 so that the service technician can check whether the electrical component arranged in the housing 1 is live or not by inserting a voltage tester through the two measuring openings 6 before removing the touch protection cover 3. The measuring openings 6 are arranged and aligned with live parts of the electrical component in such a way that the service technician can simply insert the measuring tips of the measuring device into contact with the live parts of the electrical component and measure the voltage. A warning notice 5 is also arranged on the touch protection cover 3, as well as on the housing 1, for example, in order to alert service personnel in various ways to a potentially existing hazard.

The touch protection cover 3 can be connected to the housing 1 via a loss prevention device 7 arranged in the housing 1 in accordance with FIG. 2, i.e., below the touch protection cover 3 and therefore only shown as a broken line, wherein the service cover 2 cannot be fixed to the service opening 4 if the touch protection cover 3 is not installed and therefore does not close the service opening 4. If the touch protection cover 3 is not installed, the loss prevention device 7 hangs out of the service opening 4, in particular over an edge 8 of the service opening 4, so that the service cover 2 cannot be installed tightly there. This reliably prevents the touch protection cover 3 from being forgotten. This also provides increased safety for subsequent service personnel, who do not have to worry that the previous service personnel may not have reinstalled the touch protection cover 3 correctly.

The loss prevention device 7 can be designed as a safety cable, in particular made of wire or an electrically non-conductive plastic material, thereby creating a loss prevention device 7 that is both reliable and wear-resistant and durable.

An electrical component arranged in the housing 1 can, for example, be designed as a converter. In theory, other electrical components are also conceivable. However, all electrical components have in common that they are live during operation and therefore pose a potential hazard to service personnel. If the service technician removes the service cover 2, for example to replace a fuse in housing 1, he must first check whether the electrical component arranged in housing 1 is still live. If the touch protection cover 3 were not present, the service technician would have direct access to the electrical component arranged in the housing 1 after removing the service cover 2, which would pose a significant risk to the service technician, as repairs and, in particular, maintenance work often have to be carried out under time pressure nowadays.

However, the touch protection cover 3 provided by the invention reminds the service technician once again that the electrical component arranged in the housing 1 may be live and therefore pose a hazard. The two measuring openings 6 arranged in the touch protection cover 3 also allow the responsible service technician to check the voltage safely.

To securely connect the touch protection cover 3 to the housing 1, the touch protection cover 3 can be screwed to the housing 1. In the same way, it is also possible to screw the service cover 2 to the housing 1. If screws with a lock-type screw opening are used, the service technician will need a complementary bit that acts as a key for the lock-type screws in order to be able to loosen both the service cover 2 and the touch protection cover 3.

This key-lock principle, consisting of screws and corresponding bits, prevents unauthorized persons from gaining direct access to the electrical component by unscrewing the service cover 2 or the touch protection cover 3.

In order to effectively protect the electrical component arranged in the housing 1 from water ingress, a sealing gasket may be arranged between the service cover 2 and the housing 1. Such a sealing gasket can, for example, be designed as a sealing cord with a round cross-section and enable the service opening 4 to be closed watertight by means of the service cover 2.

All in all, the housing 1 according to the invention and the touch protection cover 3 provided therein significantly increase work safety for service personnel, as they are not only warned of the risk of electric shock by warning signs 5 arranged on the service cover 2 and the touch protection cover 3, for example, but are also prevented from gaining direct access to the electrical component arranged in the housing 1 by the touch protection cover 3 when the service cover 2 is simply removed.

The loss prevention device 7 also ensures that the touch protection cover 3 cannot be lost and that the service opening 4 cannot be closed by the service cover 2 unless the touch protection cover 3 has been correctly installed beforehand.

Various examples/embodiments are described herein for various apparatuses, systems, and/or methods. Numerous specific details are set forth to provide a thorough understanding of the overall structure, function, manufacture, and use of the examples/embodiments as described in the specification and illustrated in the accompanying drawings. It will be understood by those skilled in the art, however, that the examples/embodiments may be practiced without such specific details. In other instances, well-known operations, components, and elements have not been described in detail so as not to obscure the examples/embodiments described in the specification. Those of ordinary skill in the art will understand that the examples/embodiments described and illustrated herein are non-limiting examples, and thus it can be appreciated that the specific structural and functional details disclosed herein may be representative and do not necessarily limit the scope of the embodiments.

Reference throughout the specification to “examples, “in examples,” “with examples,” “various embodiments,” “with embodiments,” “in embodiments,” or “an embodiment,” or the like, means that a particular feature, structure, or characteristic described in connection with the example/embodiment is included in at least one embodiment. Thus, appearances of the phrases “examples, “in examples,” “with examples,” “in various embodiments,” “with embodiments,” “in embodiments,” or “an embodiment,” or the like, in places throughout the specification are not necessarily all referring to the same embodiment. Furthermore, the particular features, structures, or characteristics may be combined in any suitable manner in one or more examples/embodiments. Thus, the particular features, structures, or characteristics illustrated or described in connection with one embodiment/example may be combined, in whole or in part, with the features, structures, functions, and/or characteristics of one or more other embodiments/examples without limitation given that such combination is not illogical or non-functional. Moreover, many modifications may be made to adapt a particular situation or material to the teachings of the present disclosure without departing from the scope thereof.

It should be understood that references to a single element are not necessarily so limited and may include one or more of such element. Any directional references (e.g., plus, minus, upper, lower, upward, downward, left, right, leftward, rightward, top, bottom, above, below, vertical, horizontal, clockwise, and counterclockwise) are only used for identification purposes to aid the reader's understanding of the present disclosure, and do not create limitations, particularly as to the position, orientation, or use of examples/embodiments.

“One or more” includes a function being performed by one element, a function being performed by more than one element, e.g., in a distributed fashion, several functions being performed by one element, several functions being performed by several elements, or any combination of the above.

It will also be understood that, although the terms first, second, etc. are, in some instances, used herein to describe various elements, these elements should not be limited by these terms. These terms are only used to distinguish one element from another. For example, a first element could be termed a second element, and, similarly, a second element could be termed a first element, without departing from the scope of the various described embodiments. The first element and the second element are both elements, but they are not the same element.

The terminology used in the description of the various described embodiments herein is for the purpose of describing particular embodiments only and is not intended to be limiting. As used in the description of the various described embodiments and the appended claims, the singular forms “a”, “an” and “the” are intended to include the plural forms as well, unless the context clearly indicates otherwise. It will also be understood that the phrase “at least one of” followed by successive elements separate by the word “and” (e.g., “at least one of A and B”) is to be interpreted the same as “and/or” and as used herein refers to and encompasses any and all possible combinations of one or more of the associated listed items. It will be further understood that the terms “includes,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof.

Joinder references (e.g., attached, coupled, connected, and the like) are to be construed broadly and may include intermediate members between a connection of elements, relative movement between elements, direct connections, indirect connections, fixed connections, movable connections, operative connections, indirect contact, and/or direct contact. As such, joinder references do not necessarily imply that two elements are directly connected/coupled and in fixed relation to each other. Connections of electrical components, if any, may include mechanical connections, electrical connections, wired connections, and/or wireless connections, among others. Uses of “e.g.” and “such as” in the specification are to be construed broadly and are used to provide non-limiting examples of embodiments of the disclosure, and the disclosure is not limited to such examples.

While processes, systems, and methods may be described herein in connection with one or more steps in a particular sequence, it should be understood that such methods may be practiced with the steps in a different order, with certain steps performed simultaneously, with additional steps, and/or with certain described steps omitted.

As used herein, the term “if” is, optionally, construed to mean “when” or “upon” or “in response to determining” or “in response to detecting,” depending on the context. Similarly, the phrase “if it is determined” or “if [a stated condition or event] is detected” is, optionally, construed to mean “upon determining” or “in response to determining” or “upon detecting [the stated condition or event]” or “in response to detecting [the stated condition or event],” depending on the context.

All matter contained in the above description or shown in the accompanying drawings shall be interpreted as illustrative only and not limiting. Changes in detail or structure may be made without departing from the present disclosure.

1. A housing for an electrical component, comprising:
a service cover closing a service opening; and
a touch protection cover arranged under the service cover and also closing the service opening; and
wherein the touch protection cover must be removed to access the service opening and/or an interior space of the housing.

2. The housing according to claim 1, further comprising a loss prevention device, wherein:
the touch protection cover is connected to the housing via the loss prevention device; and
the service cover cannot be fixed in place unless the touch protection cover is closing the service opening.

3. The housing according to claim 2, wherein the loss prevention device is a safety cable.

4. The housing according to claim 1, wherein the touch protection cover includes two measuring openings for a voltage tester.

5. The housing according to claim 1, wherein the housing is composed of plastic.

6. The housing according to claim 1, wherein the service cover is screwed to the housing.

7. The housing according to claim 1, wherein the touch protection cover is screwed to the housing.

8. The housing according to claim 1, further comprising a sealing gasket arranged between the service cover and the housing.

9. The housing according to claim 1, wherein the service cover closes an electrical circuit of an interlock switch.

10. The housing according to claim 1, wherein the touch protection cover includes a recess for passing an interlock switch through to the service cover.

11. The housing according to claim 1, wherein the housing is a plastic injection molded part.

12. A housing for an electrical component, comprising:
a housing body including an interior space and a service opening via which the interior space is accessible;
a service cover arranged on the housing body and closing the service opening; and
a touch protection cover arranged on the housing body under the service cover and closing the service opening; and
wherein the touch protection cover must be moved to access the service opening and/or the interior space of the housing body.

13. The housing according to claim 12, further comprising a loss prevention device connecting the touch protection cover to the housing body, wherein, when the service opening is not closed via the touch protection cover, the loss prevention device extends through the service opening and prevents the service cover from closing the service opening.

14. The housing according to claim 13, wherein the loss prevention device is a safety cable.

15. The housing according to claim 12, wherein the touch protection cover includes two measuring openings through which portions of a voltage tester are passable.

16. The housing according to claim 12, wherein the service cover is releasably connected to the housing body via a screwed connection.

17. The housing according to claim 12, wherein the touch protection cover is releasably connected to the housing body via a screwed connection.

18. The housing according to claim 12, further comprising a sealing gasket arranged between the service cover and the housing body via which the service opening is sealable in a fluid tight manner.

19. The housing according to claim 12, wherein the service cover is configured to engage an interlock switch when arranged on and/or removed from the housing body.

20. The housing according to claim 19, wherein the touch protection cover includes a recess via which the service cover and the interlock switch interact.
